(19) United States
(12) Patent Application Publication
(10) Pub. No.: US 2012/0042937 A1
(43) Pub. Date: Feb. 23, 2012

(54) PARTITIONED CURRENT MATCHING SOLAR CELL

(76) Inventor: Donald J. Wagner, Los Gatos, CA (US)

(21) Appl. No.: 12/860,888

(22) Filed: Aug. 21, 2010

(51) Int. Cl. H01L 31/0352

(52) U.S. Cl. 136/255

(57) ABSTRACT

A partitioned current matching solar cell wherein each partition has the same current. The solar cell provides for matched current within a single junction solar cell or across junctions within a multi-junction solar cell. A focusing detector is also provided.

### BACKGROUND OF THE INVENTION

1. Field of the Invention

This invention relates to the solar cells and more particularly to a current matching multijunction solar cell partitioned such that each partition has the same current.

2. Description of the Prior Art

In a semiconductor, a conduction band and a valance band are separated by an energy gap E_{g} that varies with material, composition and temperature. A photon of wavelength λ (as measured in a vacuum) and frequency ν has an energy hν=hc/λ (where h is Planck's Constant) and can be absorbed by a semiconductor when hν≧E_{g}. However, any extra energy in the photon (hν−E_{g}) is converted into thermal rather than electrical energy, since only one electron-hole pair can be created for each absorption event. On the other hand, a semiconductor is more transparent to wavelengths corresponding to energies less than E_{g}, since in this case the photons are not energetic enough to promote electrons from the valence band into the conduction band. Thus, no single semiconducting material can convert the entire solar spectrum into electrical energy, since the most energetic photons produce largely thermal energy and are therefore inefficiently utilized, while the least energetic photons cannot be absorbed. However, by cascading the p-n junctions of different materials, the overall conversion efficiency can be improved. In multijunction solar cells, a top junction having a p-n junction of a high energy band gap semiconductor intercepts the most energetic photons. Lower energy photons pass through the top junction before they enter another junction having a p-n junction of a lower energy band gap semiconductor. In this way, an additional portion of the solar spectrum is used. For example if a photon of red light with a wavelength of 700 nm and an energy level of 1.77 eV is absorbed by Ge which had a band gap of 0.69 eV, then 0.69 eV will be turned into electricity and the rest of the energy will create heat. If the band gap is too high then it will not generate any electricity but will be go through the material, be scattered or create heat.

To maximize the amount of electricity from sunlight, it is necessary to have materials that segregate the sunlight into different band gap material. The power (P) will be current (I) times the Voltage (V) or P=I×V. If cells are connected in series, the voltage is the sum of the voltage drops across the cell multiplied by the minimum current of all the cells. Since the cell with the lowest current will determine the current of the whole circuit, it is optimal to have all the currents the same (current matched). This can be done by changing the cells chemical composition which alters the bandgap, or by altering the thickness so that more or fewer photons are absorbed in a particular cell. Junctions in a solar cell behave similarly.

In the discussion that follows, the calculations in the tables are based on data from ASTM G-173, and assume no concentration and a perfect fill factor.

For Air Mass 1.5 Direct (AM1.5D) meter̂2 single junction solar cell the theoretical best band gap would be 1.33 eV with energy of 429.79 watts. For a two junction current matched cell it would be 1.11 eV and 1.82 eV producing 568.03 watts. A triple junction cell with the most power would have bandgaps of 0.73 eV, 1.38 eV and 2.0 eV. This configuration would yield 682 watts of energy, but when hooked up in series will only produce 546 watts (see table 1).

TABLE 1
Best Power AM1.5D

| | Wavelength | | Current | Energy |
|---|---|---|---|---|
| Layer | nm | Voltage eV | Amps | watts |
| 1 | 620 | 2 | 132.85 | 265.71 |
| 2 | 900 | 1.38 | 175.34 | 241.58 |
| 3 | 1700 | 0.73 | 240.18 | 175.19 |
| | | | | 682.4756 |
| | | | Min | |
| | | V Total | Current | Electricity |
| | | 4.11 | 132.8528 | 545.65 |

Current matching the junctions using bandgaps of 1.0 eV, 1.41 eV and 1.93 eV (see table 2) would

TABLE 2
Best Current matched AM1.5D

| | Wavelength | | Current | Energy |
|---|---|---|---|---|
| Layer | nm | Voltage eV | Amps | watts |
| 1 | 644 | 1.93 | 148.65 | 286.22 |
| 2 | 880 | 1.41 | 148.13 | 208.73 |
| 3 | 1241 | 1.00 | 148.25 | 148.13 |
| | | | | 643.08 |
| | | | Min | |
| | | V Total | Current | Electricity |
| | | 4.33 | 148.13 | 641.40 |

yield less power if the junctions were separated (683 watts versus 643 watts), but when connected in series, the energy would be 642 watts versus 546 watts. For this reason there has been much research to solve the current matching problem. U.S. Pat. No. 5,716,459 has multiple partitions on one monolithic solar cell but does not current match the separate junctions. U.S. Pat. No. 5,223,043 and U.S. Pat. No. 6,281,426 achieve a better current match by changing the thickness of the junctions, giving non-optimal energy efficiency. In a paper by D. Aiken, he suggested using two layers of Ge since there is an excess of current, raising the voltage by 0.69 eV. U.S. Pat. No. 6,316,715 has essentially the same implementation of using multiple junctions of the same material but extends it to more than just the bottom layer. The prior art from U.S. Pat. No. 6,316,715 is shown in FIG. 1 with 3 material systems shown (1, 2 and 3) where material system 1 has two junctions (1A and 1B) and material system 2 also has two junctions (1A and 2B).

Most previous attempts to resolve the current matching problem have focused on matching the current of the different junctions. “To achieve maximum energy conversion efficiency: 1) the junctions must be fabricated from materials that are of high electronic quality (usually achieved from systems that are lattice matched), and 2) they must also be current matched, i.e. generate equal currents when exposed in the tandem configuration to the solar spectrum.” J. C. C Fan B. Y. Tsaur and B. J. Palm, Proceedings of the 16^{th} IEEE Photovoltaic Specialists Conference (IEEE, New York, 1982), P. 692

A notable exception is U.S. Pat. No. 5,853,497 (FIG. 3 Lillington), that discloses connecting the two upper layers in series then partitioning the lower two layers into three partitions and connecting those in parallel. Another nonstandard implementation using multiple solar cells was proposed by Frass et al (FIG. 2 Frass) wherein the three top cells are connected to each other in parallel along with three bottom cells.

For creating irregular partitions in solar cells, international application WO/2009/033215 discloses an array of solar cells wherein the solar cells are of varying dimensions or areas. More particularly, it discloses an array wherein the solar cells are provided in a range of shapes including circles, trapezoids, rectangles, or squares. U.S. Pat. No. 5,716,459 also discloses a microarray wherein the solar cells have a non-rectangular shape.

For self focusing solar cells, U.S. Pat. No. 7,206,142 shows a set of separate solar cells or separate bands on the same solar cell that are based on separating sunlight using chromatic aberration. The self focusing feature needs to be made as a separate step in the manufacturing process and can only support a single-axis tracker.

Another problem is that with most typical concentration systems the distribution of light (irradiance) is uneven (FIG. 8), with the corresponding sections of the solar cell producing a corresponding amount of current. While irradiance matching has been mentioned as an issue there are no solutions published other than compensating for it in the primary optic or having a secondary optic to compensate for the problem.

There is therefore a need in the art for a current matching multijunction solar cell that overcomes the limitations of the prior art due to current mismatches between the junctions and between different portions of the solar cell.

### SUMMARY OF INVENTION

The invention is a partitioned multi-junction solar cell that is partitioned so that each partition has the same current. The partitioning provides for an approximately equal current across junctions.

In another aspect of the invention, a partitioned solar cell comprises partitions of different sizes to match the irradiance profile, the partitions having the same current.

In yet another aspect of the invention, a partitioned solar cell comprises partitions that are compared to determine if the partitioned solar cell is in focus.

### BRIEF DESCRIPTION OF THE DRAWINGS

FIG. 1 is an isometric view of a multijunction solar cell of the prior art;

FIG. 2 is a schematic representation of a two junction solar cell of the prior art;

FIG. 3 is an isometric view and electrical diagram of a multijunction solar cell of the prior art;

FIG. 4 is an isometric view of an optimal AM1.5D triple junction solar cell;

FIG. 5 is an isometric view of an optimal AM0 triple junction solar cell;

FIG. 6 is an electrical diagram of an optimal AM1.5D triple junction solar cell;

FIG. 7 is an electrical diagram of an optimal AM0 triple junction solar cell;

FIG. 8 is a side view of a prior art refractive concentration system;

FIG. 9 is a top plan view of the current for different parts of a solar cell produced by a first irradiance profile;

FIG. 10 is a top plan view of the equal current partitions with the currents shown;

FIG. 11 is a top plan view of equal current partitions without the currents shown;

FIG. 12 is a top plan view of the current for different parts of a solar cell produced by a second irradiance profile;

FIG. 13 is a top plan view of the equal current partitions with the currents shown;

FIG. 14 is a top plan view of equal current partitions without the currents shown;

FIG. 15 is an isometric view of an exemplary partitioned solar cell; and

FIG. 16 is an isometric view of a self focusing partitioned solar cell.

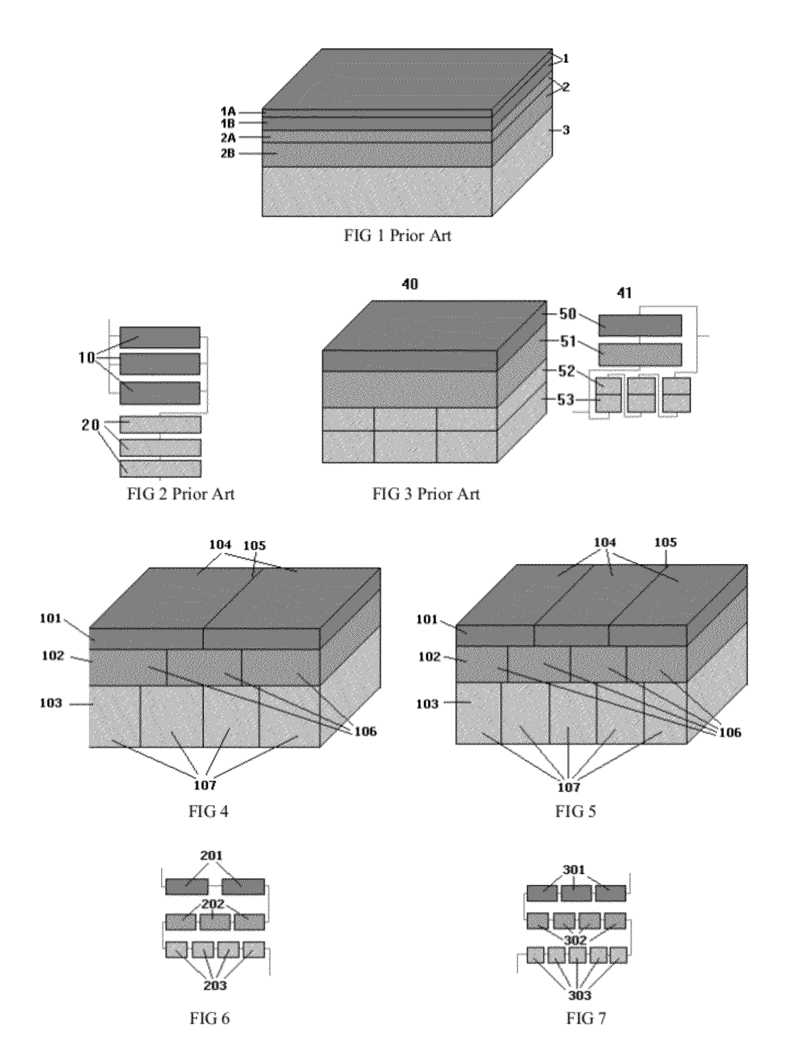

### DETAILED DESCRIPTION OF THE INVENTION

The present invention solves the current matching problem across different junctions of a solar cell by partitioning the junctions such that each partition and each junction has the same current. Partitions of varying sizes are provided to compensate for current mismatches due to irregular irradiance profiles.

Partitioning the junctions of a solar cell allows the current to be matched across the junctions. At AM1.5D for a theoretical triple junction cell (FIG. 4) that can have any bandgap, using 2, 3 and 4 partitions for the first, second and third junctions respectively (with the first layer facing the sun and using a bandgap of 2.06, 1.40 and 0.74) 678.45 watts of power are provided (Table 3) which is a 5.75% improvement. In theory hundreds or thousands of partitions are possible, but the minimal partition would still limit the current, so the maximal energy will typically be derived from the fewest partitions as possible while still providing a close match for the current. The electrical connections (all partitions are in series) are shown in FIG. 6.

TABLE 3
Best Partitioned AM1.5D

| | Wave- | Volt- | | | | | |
|---|---|---|---|---|---|---|---|
| | length | age | Current | Energy | | | |
| Layer | nm | eV | Amps | watts | C2 | V2 | Partitions |
| 1 | 601 | 2.06 | 120.49 | 248.6 | 60.25 | 4.13 | 2 |
| 2 | 888 | 1.40 | 181.19 | 253.02 | 60.40 | 4.19 | 3 |
| 3 | 1680 | 0.74 | 241.66 | 178.37 | 60.42 | 2.95 | 4 |
| | | | | 679.99 | | | |
| | | V | Min | Elec- | Min | V | |
| | | Total | Current | tricity | Current | Total | |
| | | 4.20 | 120.49 | 505.79 | 60.25 | 11.27 | 678.85 |

For AM0 (FIG. 5) the maximum power for three separate cells is 1008.12 watts. The best current matched cell produces 969.06 watts and the best partitioned cell produces 1007.89 watts (see tables 4, 5, 6) or a 4% improvement over the previous best solution. The electrical connections (all partitions are in series) are shown in FIG. 7.

TABLE 4
Best Power AM0

| Layer | Wavelength | Voltage eV | Current | Energy |
|---|---|---|---|---|
| 1 | 593 | 2.09 | 197.12 | 412.200 |
| 2 | 939 | 1.32 | 269.10 | 355.360 |
| 3 | 1700 | 0.73 | 329.80 | 240.560 |
| | | | | 1008.12 |
| | | V Total | Min | Electricity |
| | | 4.14 | 197.1247 | 816.30 |

TABLE 5
Best Current matched AM0

| Layer | Wavelength | Voltage eV | Current | Energy |
|---|---|---|---|---|
| 1 | 629 | 1.97 | 232.86 | 459.06 |
| 2 | 943 | 1.31 | 232.56 | 305.80 |
| 3 | 1408 | 0.88 | 232.71 | 204.94 |
| | | | | 969.80 |
| | | V Total | Min | Electricity |
| | | 4.17 | 232.56 | 969.06 |

TABLE 6
Best Partitioned Electricity AM0

| | Wave- | Volt- | | | | | |
|---|---|---|---|---|---|---|---|
| Layer | length | age | Current | Energy | Cpar | Vpar | Partitions |
| 1 | 588 | 2.11 | 198.12 | 417.810 | 66.04 | 6.33 | 3 |
| 2 | 938 | 1.32 | 264.13 | 349.170 | 66.03 | 5.29 | 4 |
| 3 | 1699 | 0.73 | 330.17 | 240.970 | 66.03 | 3.65 | 5 |
| | | | | 1007.95 | | | |
| | | V | Min | Elec- | Min | V | Elec- |
| | | Total | | tricity | Current | Total | tricity |
| | | 4.16 | 198.12 | 824.32 | 66.03 | 15.26 | 1007.89 |

Using actual cells the improvement goes up dramatically. Using the bandgaps and currents disclosed by Daniel J. Aiken in InGaP/GaAs/Ge Multi-Junction Solar Cell Efficiency Improvements Using Epitaxial Germanium (Sandia National Laboratories, Albuquerque, N. Mex.), a 42% improvement is achieved. Using the bandgaps disclosed by Steve Lansel, Technology and Future of III-V Multi-Junction Solar Cells, (www.stanford.edu/˜slansel/projects/solar %20report.doc), and using partitions of 4, 2 and 5 for the 1^{st} 2^{nd} and 3^{rd} layers respectively, a significant 68% improvement (see table 7) is achieved.

TABLE 7

| | Current Technology | | | | | | | |
|---|---|---|---|---|---|---|---|---|
| | wavelength | Voltage | | | Partitioned | | | |
| | nm | eV | Current | Energy | C2 | V2 | Partitions | Improvement |
| Aiken | 667 | 1.86 | 22.1 | 41.106 | 7.37 | 5.58 | 3 | |
| | 873 | 1.42 | 15.6 | 22.152 | 7.80 | 2.84 | 2 | |
| | 1879 | 0.66 | 42.4 | 27.984 | 7.07 | 3.96 | 6 | |
| | | 3.94 | 15.6 | 61.464 | | | | |
| | | Total eV | Min | Total | Min | V Total | Total | |
| | | | current | | Current | | | |
| | | | | | 7.07 | 12.38 | 87.49 | 42% |
| | | | Current | | | | | |
| | wavelength | Voltage | (mA/ | Energy | | | | |
| | nm | eV | cm\hat{ }2) | watts | C2 | V2 | Partitions | Improvement |
| Lansel | 689 | 1.8 | 282.31 | 508.15 | 70.58 | 7.20 | 4 | |
| AM0 | 886 | 1.4 | 145.64 | 203.90 | 72.82 | 2.80 | 2 | |
| | 1771 | 0.7 | 370.50 | 259.35 | 74.10 | 3.50 | 5 | |
| | | 3.9 | 145.64 | 568 | | | | |
| | | Total eV | Min | Total | Min | V Total | Total Watts | |
| | | | current | watts | Current | | | |
| | | | | | 70.58 | 13.50 | 952.78 | 68% |

The advantage of partitioning the junctions is that the current is easily matched in the majority of cases regardless of the initial bandgaps. The partitioning technique can be combined with varying the thickness or composition of the junction to make fine adjustments to create the optimal multiple junction solar cell for the irradiance profile. This can easily be done with two, three or more junctions.

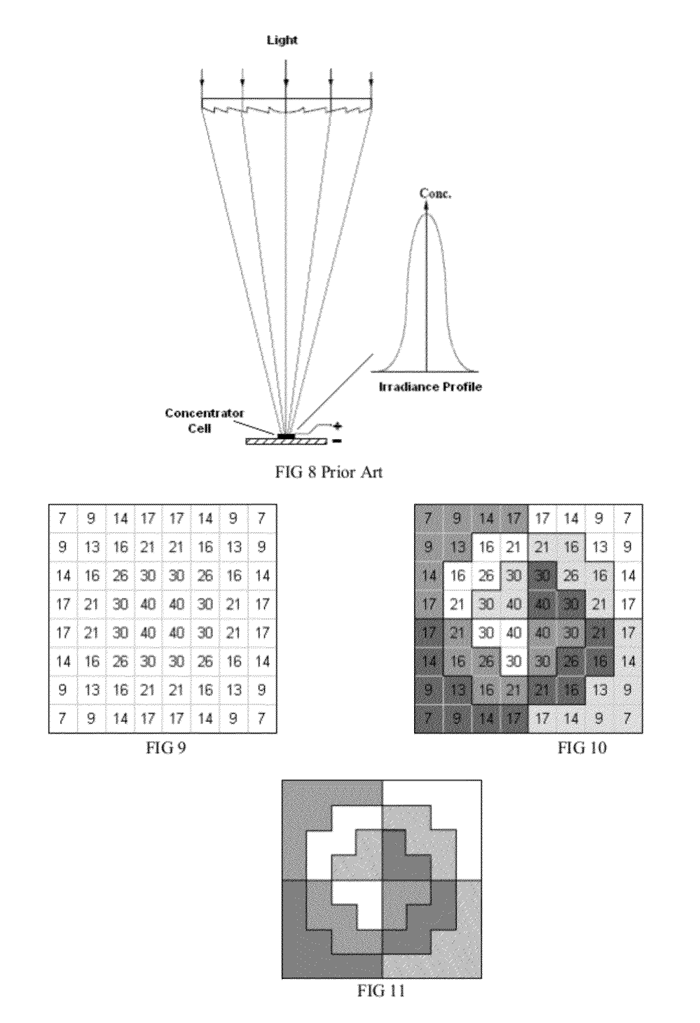

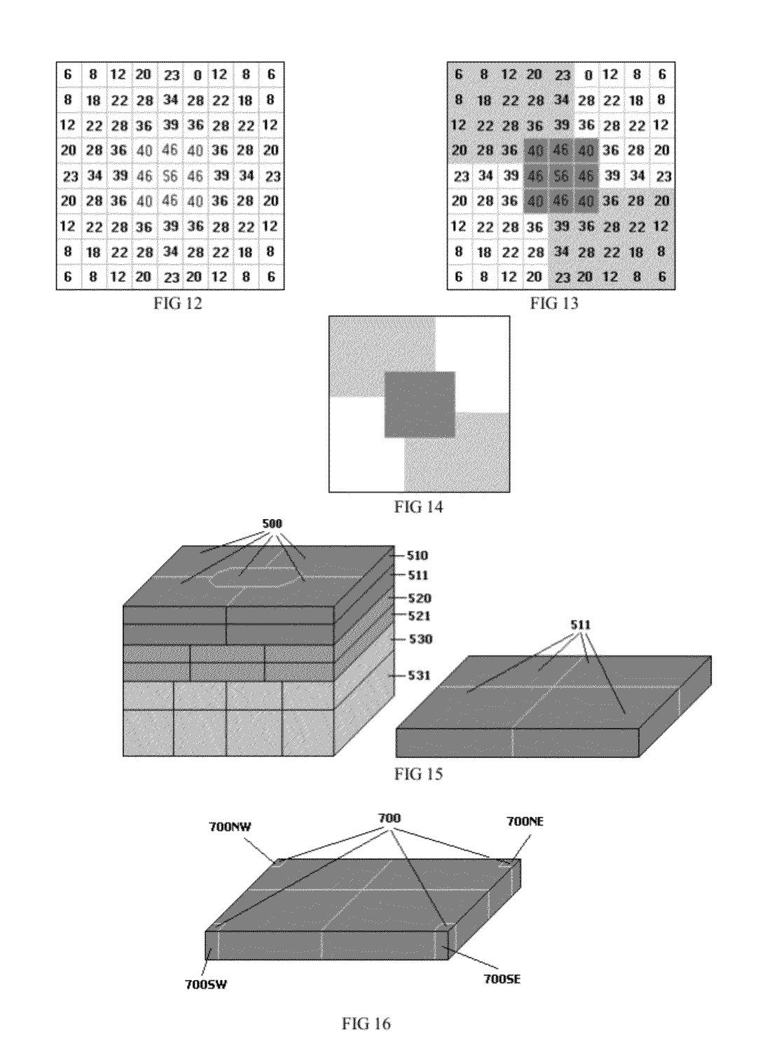

FIG. 8 shows a specific irradiance profile when concentrating light. FIG. 9 and FIG. 12 show top plan views of the current distribution of the solar cell due to the uneven irradiance distribution. FIG. 10 shows nine groups that each have 100 units of current for each section. FIG. 13 shows the nine different partitions. FIG. 11 shows the nine partitions for the first irradiance profile. FIG. 15 shows the 5 partitions of non-rectilinear shape for the second irradiance profile. By using several partitions of unequal areas that have equal current, the junction will be more efficient.

FIG. 16 shows the focusing detector incorporated into the solar cell 700. The detector can be in any part of the cell, but will typically be on the corner edges. Comparing the current of the focusing detectors on one side of the cell (700NW, 700NE) with the current from the other side of the solar cell (700SW, 700SE) it can be determined if the cell is focused along the north south axis, and if not, which direction the cell (and panel) needs to move. By similarly comparing the current on one side of the cell (700SW, 700SE) with the current from the other side of the solar cell (700NW, 700NE) it can be determined if the cell is focused along the East West axis, and if not, which direction the cell (and panel) needs to move. The focusing detector can be used to initially place and calibrate the solar cell 700.

One example of an embodiment would be a theoretical AM1.5 (FIG. 4) and AM0 (FIG. 5) where any bandgap can be produced. The three junctions 101, 102 and 103 are shown respectively and the partitions for the first junction 104, and the divisions in the first junction 105 the partitions in the second junction 106, and finally the partitions in the third junction 107 are shown. These are the optimal partitions for a AM1.5D and AM0 triple junction solar cell using less than ten partitions. The corresponding electrical diagrams are shown in FIG. 6 and FIG. 7.

Another embodiment provides using multiple bandgap materials with some or all having one or more junctions and each junction being partitioned so that every junction has the same current. One example of this type of embodiment is shown in FIG. 15. In this embodiment, there are three different bandgap materials, each with two junctions. The first bandgap material has two junctions. In the first junction of the first material, it has five partitions 500 in the first junction. The second junction of the first material system 510 has four partitions in the second junction. The middle bandgap material has two junctions 520 and 521, each with three partitions. The bottom bandgap material also has two junctions 530 and 531 both of which have four partitions. Note that the bottom junction of the bottom bandgap material is thicker which will be typical since the energy is exponentially proportional to the depth of the material. The top gathers some of the energy leaving less energy to be gathered so the lower layer so more material is needed to pick up the same amount of energy.

Similar embodiments can be used for two junction solar cell, four junction solar cells or N junction solar cells where N is less than infinity. Similarly the irradiance profiles can be combined with the partitioning of the different junctions.

I claim:

1. A multiple junction solar cell comprising:
at least one partitioned junction, each partition of the partitioned junction having substantially the same current and each junction having substantially the same current.

2. The multiple junction solar cell of claim 1, wherein the partitions are rectilinear, non-rectilinear or a combination of both.

3. The multiple junction solar cell of claim 1, wherein the partitioned junctions can have different thicknesses to provide for a favorable current and bandgap match.

4. The multiple junction solar cell of claim 1, wherein the partitioned junctions are connected in series.

5. The multiple junction solar cell of claim 1, wherein certain of the partitions are compared to each other to determine if the solar cell is in focus.

6. The multiple junction solar cell of claim 5, wherein the partitions comprise corner partitions of the solar cell.

7. The multiple junction solar cell of claim 5, wherein compared currents of the partitions are used to initially place and calibrate the solar cell.

8. A solar cell comprising:
one or more junctions partitioned into a number of irradiance matching partitions, each partition producing substantially the same current.

9. The solar cell of claim 8, wherein the partitions are rectilinear, non-rectilinear or a combination of both.

10. The solar cell of claim 8, wherein the partitions are determined by an irradiance profile.

11. The solar cell of claim 8, wherein certain of the partitions are compared to each other to determine if the solar cell is in focus.

12. The solar cell of claim 11, wherein the partitions comprise corner partitions of the solar cell.

13. The solar cell of claim 11, wherein compared currents of the partitions are used to initially place and calibrate the solar cell.
